(19) United States
(12) Patent Application Publication
(10) Pub. No.: US 2008/0130217 A1
(43) Pub. Date: Jun. 5, 2008

(54) Swappable data access unit rack structure installable in a computer casing

(76) Inventor: Wei-Ping Chen, Taipei (TW)

Correspondence Address: WEI-PING CHEN, 235 Chung - Ho, Box 8-24, Taipei, omitted

(21) Appl. No.: 11/633,226

(22) Filed: Dec. 5, 2006

(51) Int. Cl. H05K 5/02

(52) U.S. Cl. 361/685; 361/687

(57) ABSTRACT

In a swappable data access unit rack structure installable in a computer casing, a chassis is a box body composed of a lower casing, a front frame, a rear panel and an upper casing. The front frame has a frame hole, a transversal long hole at its upper edge, and a frame at the rear of the front frame. An upper distal surface of the frame is of the same height with a lower edge of the long hole of the front frame. A rack panel is fixed at the upper edge of the inner side of the lower casing. The long hole, the upper distal surface of the frame and the rack panel define a horizontal bay and a tray for carrying a data access unit. The tray is slidably slid into the bay and mounted across the upper distal surface of the frame and the rack panel.

### BACKGROUND OF THE INVENTION

1. Field of the Invention

The present invention relates to a swappable data access unit rack structure installable in a computer casing, and more particularly to its application for industrial computer casings and the installation of related data access units, wherein the data access unit is installed onto the tray, and the tray is passed through the bay and mounted at the upper edge of the front lateral side of the chassis to improve the installation of a data access unit of a traditional industrial computer, so as to provide a swappable and convenient application while improving the heat dissipation of chassis and conforming with the application requirements for different models of motherboards.

2. Description of the Related Art

Referring to FIGS. 1 and 2 for a traditional industrial computer chassis and its internal layout, the front side of a chassis 10 has a front panel 11, and the front panel 11 has a pivotal door panel 12 and a plurality of ventilation holes 13, and the rear side of the front panel 11 has a disk rack 14 for installing a data access unit and its interior sequentially has a partition 16 with a plurality of fans 15, a motherboard (not shown in the figure) disposed on the bottom of the space at the rear of the partition 16, and a rear panel 17, and the rear panel 17 has a plurality of interface card slots 170. However, the traditional computer chassis has the following shortcomings:

Firstly, the front panel 11 has a plurality of ventilation holes 13 and a fan 15 to draw cool air from the outside into a computer chassis through the ventilation holes and blown at heat generating components of the motherboard, but the airflow is blocked by the disk rack. As a result, the insufficient incoming airflow cannot provide a good heat dissipating effect, and such arrangement also produces low-frequency noises of the airflow.

Secondly, the partition 16 with fans 15 are disposed at the disk rack 14, and the fans 15 have to maintain an appropriate distance apart for allowing the air to flow through, and thus the disk rack 14 will occupy too much space, and the spaces for the partition 16 and the rear panel 17 will be reduced and arranged with an irregular shape. Therefore, the space of the standard specification can be used for the layout of a small motherboard, but it cannot be used for installing a larger and more powerful motherboard (such as a motherboard with a dual core CPU).

Thirdly, the data access unit (such as a hard disk, a floppy disk or an optical disk) is installed on the disk rack 14, and the data access unit is pushed from the front of the chassis 10 for its installation. The front panel of the data access unit is disposed at an external edge of a frame hole of the disk rack 14 and the data access unit is secured onto the disk rack 14. If it is necessary to change or repair the data access unit, the chassis 10 is pulled out from the chassis array (industrial computer chasses are generally stacked and combined into a chassis array), and the lower casing is removed, and the locking elements are unsecured in order to remove, change or repair the data access unit. After the change or examination of the data access unit is completed, it is necessary to reinstall the data access unit, and such arrangement is very inconvenient, time-consuming, and laborious.

### SUMMARY OF THE INVENTION

In view of the foregoing shortcomings of the present invention, the inventor of the present invention lower casing on years of experience on the related field to conduct extensive experiments and modifications and finally developed a swappable data access unit rack structure installable in a computer casing in accordance with the present invention.

Therefore, it is a primary objective of the present invention to provide a swappable data access unit rack structure installable in a computer casing, wherein the data access unit is installed on the tray and slidably disposed at an upper edge on a front lateral side of the chassis, so that the invention can achieve a good convection for the heat dissipating effect without installing a traditional disk rack.

The secondary objective of the present invention is to provide a swappable data access unit rack structure installable in a computer casing that contains a data access unit tray disposed at an upper edge on a front lateral side of the chassis, so that the internal layout of the chassis can be rearranged to provide an open installing space for installing different models of motherboards.

A further objective of the present invention is to provide a swappable data access unit rack structure installable in a computer casing, wherein the tray can be pushed into the chassis or pulled out from the chassis easily, and thus providing a quick and convenient way for changing or examining a data access unit.

To achieve object, the present invention provides a swappable data access unit rack structure installable in a computer casing, comprising: a chassis which is a box body comprised of a lower casing, a front frame, a rear panel and an upper casing, wherein said front frame has a frame hole and a transversal long hole disposed at its upper edge, and a rear side of said front frame has a frame, and an upper distal surface of said frame is of the same height with a lower edge of said long hole of said front frame, and another side has a rack panel is fixed onto an upper edge of an internal side of said lower casing, and said long hole, the upper distal surface of said frame and said rack panel form a horizontal bay, and a tray is provided for carrying a data access unit, and said tray is slidably passed through said bay and mounted across the upper distal surface of said frame and said rack panel.

With the foregoing arrangement, a data access unit of the invention can be installed on a tray and slidably positioned at an upper edge on a front lateral side of the chassis to provide a good convection for the heat dissipation of the chassis. In the meantime, the interior of the chassis provides an open installing space for installing different models of motherboards, and the data access unit can be changed or examined easily by pulling out the tray. In other words, the invention definitely can provide a simple, easy, quick and convenient application.

### BRIEF DESCRIPTION OF THE DRAWINGS

FIG. 1 is a perspective view of a traditional industrial computer casing;

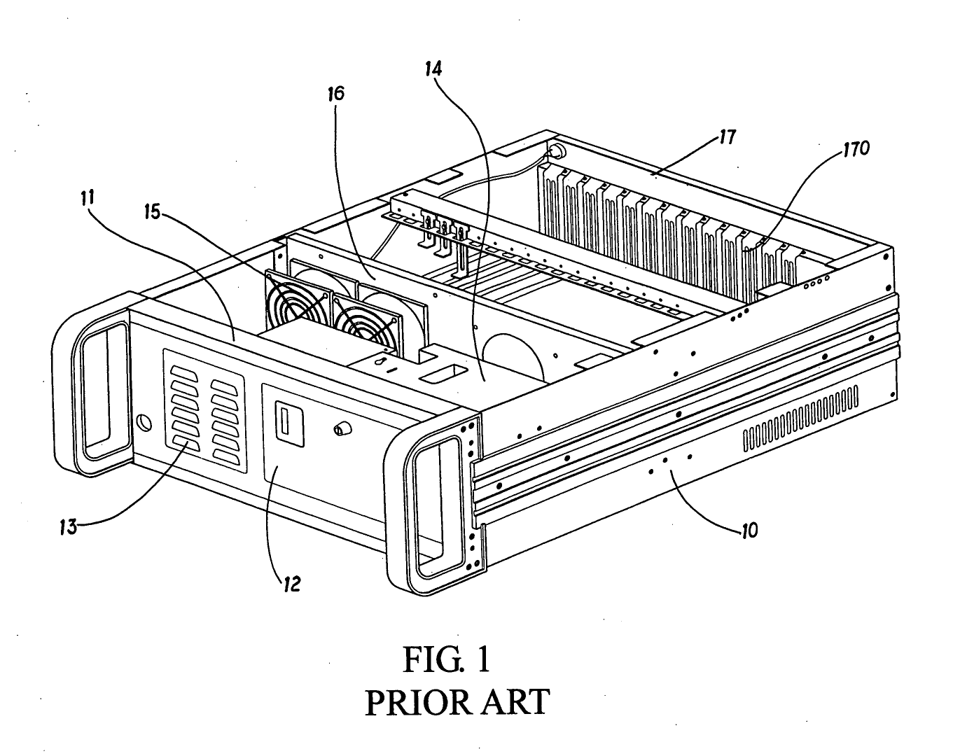

FIG. 2 is a schematic rear view of FIG. 1;

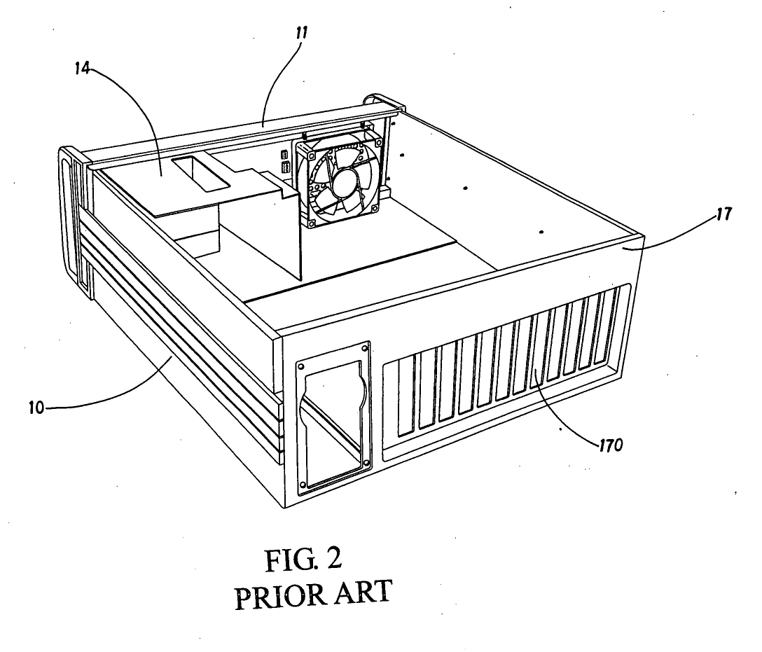

FIG. 3 is a schematic view of installing a computer casing of the present invention;

FIG. 4 is a perspective view of a front panel of the present invention;

FIG. 5 is a perspective view of an assembly of the present invention;

FIG. 6 is a schematic view of combining a tray and a frame in accordance with the present invention;

FIG. 7 is a schematic view of installing an access unit on a tray in accordance with the present invention; and

FIG. 8 is a schematic view of guiding airflows in an installed computer casing in accordance with the present invention.

### DETAILED DESCRIPTION OF THE PREFERRED EMBODIMENTS

The above and other objects, features and advantages of the present invention will become apparent from the following detailed description taken with the accompanying drawing.

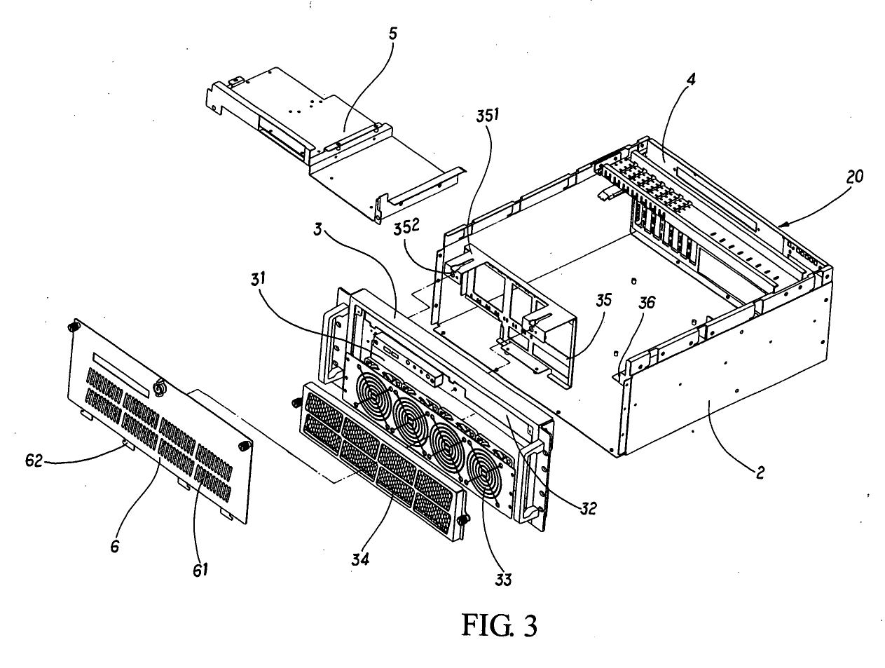

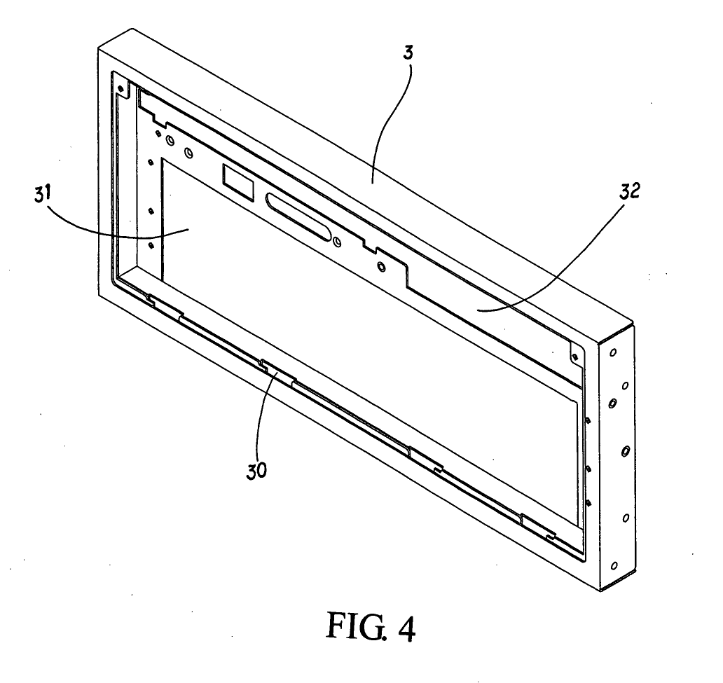

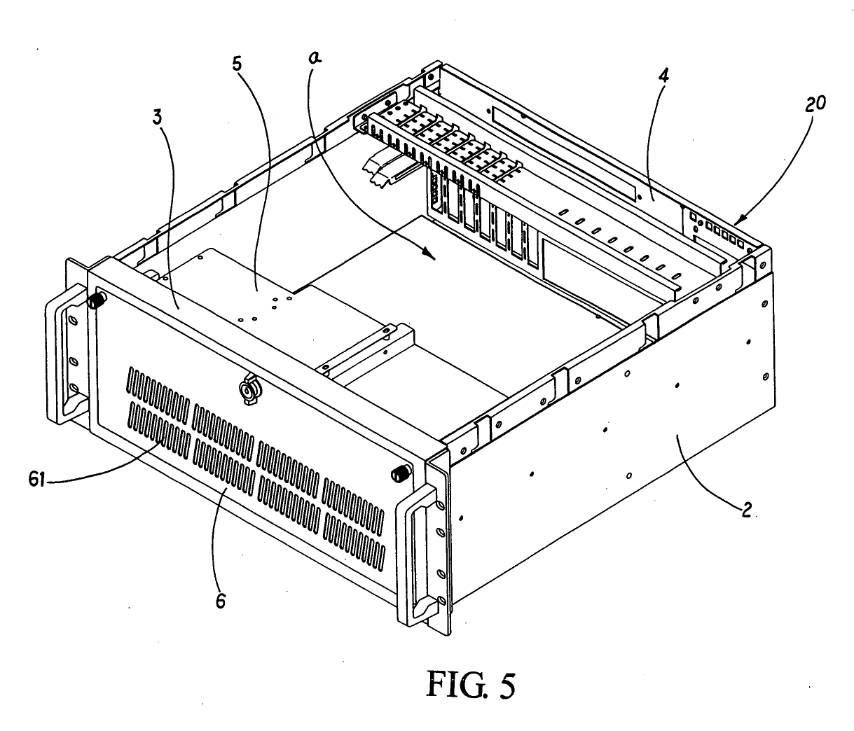

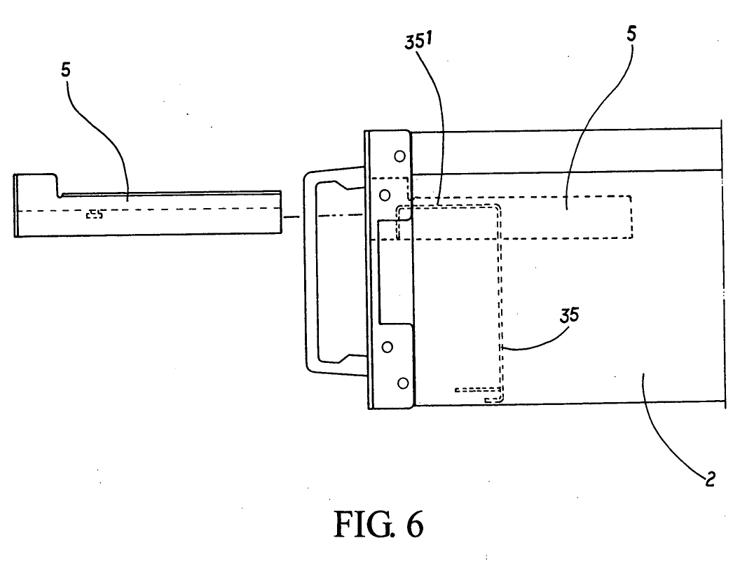

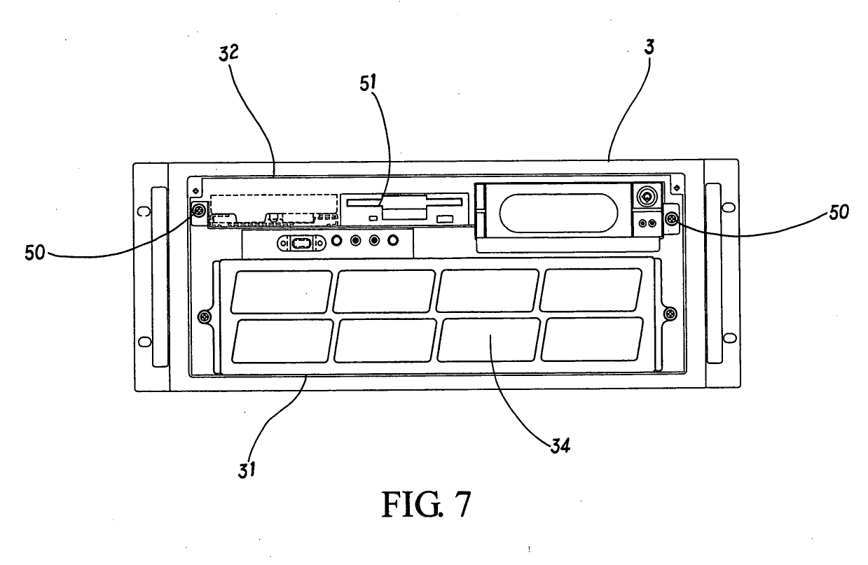

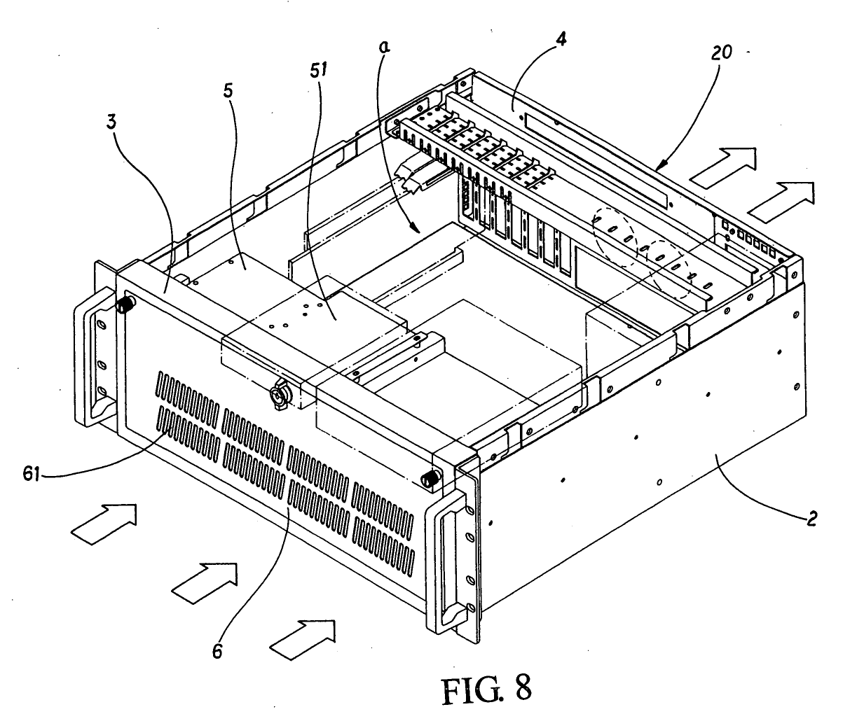

Referring to FIGS. 3 to 5 for a swappable data access unit rack structure installable in a computer casing in accordance with the present invention, a chassis 20 is a box body including a lower casing 2, a front frame 3, a rear panel 4 and an upper casing (not shown in the figure), wherein the front frame 3 is disposed at the front side of the lower casing 2 and has a frame hole 31 and a transversal long hole 32 disposed at its upper edge, and the frame hole 31 contains a fan module 33, and a front side of the fan module 33 has a filter 34, and the rear side of the front frame 3 has a frame 35, wherein an upper distal surface 351 of the frame 35 is of the same height with a lower edge of the long hole 32 of the front frame 3, and another side has a rack panel 36 fixed at an upper edge on the internal side of the lower casing 2, and the long hole 32, the upper distal surface 351 of the frame 35 and the rack panel 36 form a transversal bay and a tray 5 for carrying a data access unit 51, and both ends separately have a locking element 40, and the tray 51 is slidably passed through the bay and mounted across the upper distal surface 351 of the frame 35 and the rack panel 36 (as shown in FIGS. 6 and 7), and locking elements 50 are secured with the screw holes 352 to achieve a secured connection, so that the tray 5 containing the data access unit 51 can be pushed and positioned at the upper edge on the front lateral side of the chassis 20. The front frame 3 has a frame hole 31, and its bottom has a plurality of through holes 30, and the door panel 6 has a ventilation hole 61 corresponding to the frame hole 31 and its bottom has a rotating axis 62 inserted correspondingly into the through hole 30 such that the door panel 6 can be pivotally coupled to a front lateral side of the chassis 20 and precisely engaged with the front frame 3. With the foregoing arrangement, cool air can be drawn from the outside into the chassis 20 through the ventilation holes 61 (as shown in FIG. 8) and blown directly at heat generating electronic components (not shown in the figure) in the chassis 20, so as to achieve a good heat dissipating effect.

If it is necessary to change or repair the data access unit 51, users simply loosen the locking elements 50 and pull the tray 5 out from the bay for a quick, simple and easy replacement or repair. Further, the data access unit 51 of the invention is installed on the tray 5 and situated at the upper edge on the front lateral side of the chassis, such that an open installing space (a) is formed in the lower casing 2 between the frame 35 and the rear panel 4 for installing different models or specifications of motherboards. The present invention can provide sufficient space for expansions and upgrades.

What is claimed is:

1. A swappable data access unit rack structure installable in a computer casing, comprising: a chassis which is a box body comprised of a lower casing, a front frame, a rear panel and an upper casing, wherein said front frame has a frame hole and a transversal long hole disposed at its upper edge, and a rear side of said front frame has a frame, and an upper distal surface of said frame is of the same height with a lower edge of said long hole of said front frame, and another side has a rack panel is fixed onto an upper edge of an internal side of said lower casing, and said long hole, the upper distal surface of said frame and said rack panel form a horizontal bay, and a tray is provided for carrying a data access unit, and said tray is slidably passed through said bay and mounted across the upper distal surface of said frame and said rack panel.

2. The swappable data access unit rack structure installable in a computer casing of claim 1, wherein said front frame has a frame hole and a transversal long hole disposed at its upper edge, and said frame hole contains a fan module.

3. The swappable data access unit rack structure installable in a computer casing of claim 1, wherein said chassis has a door panel pivotally coupled to a front end of said chassis and engaged correspondingly and precisely with said front frame.

4. The swappable data access unit rack structure installable in a computer casing of claim 1, wherein said long hole of said front frame has a screw hole disposed separately on both sides of said long hole, and both ends of said tray have a locking element, and said tray is passed through said bay and mounted across an upper distal surface of said frame and said rack panel, and said locking elements are secured into said screw holes respectively.

5. The swappable data access unit rack structure installable in a computer casing of claim 1, wherein said front frame has a frame hole and a transversal long hole disposed at its upper edge, and said frame hole contains a fan module, and the front side of said fan module has a filter.

6. The swappable data access unit rack structure installable in a computer casing of claim 3, wherein said front frame has a frame hole and its bottom has a plurality of through holes, and said door panel has a ventilation hole corresponding to said frame hole, and its bottom has a rotating axis inserted correspondingly into said through hole, and a door panel is pivotally coupled to the front lateral side of said chassis.
